(19) United States
(12) Patent Application Publication
(10) Pub. No.: US 2011/0081771 A1
(43) Pub. Date: Apr. 7, 2011

(54) MULTICHAMBER SPLIT PROCESSES FOR LED MANUFACTURING

(75) Inventor: JIE SU, Santa Clara, CA (US)

(73) Assignee: APPLIED MATERIALS, INC., Santa Clara, CA (US)

(21) Appl. No.: 12/897,429

(22) Filed: Oct. 4, 2010

Related U.S. Application Data
(60) Provisional application No. 61/249,470, filed on Oct. 7, 2009.

(51) Int. Cl. H01L 21/20

(52) U.S. Cl. 438/508; 438/507; 257/E21.09

(57) ABSTRACT

Embodiments described herein generally relate to methods for forming Group III-V materials by metal-organic chemical vapor deposition (MOCVD) processes and/or hydride vapor phase epitaxial (HVPE) processes. In one embodiment, deposition of a group III₁-N layer on a substrate is performed in a first chamber, deposition of a group III₂-N layer on the substrate is performed in a second chamber, and deposition of a group III₃-N layer on the substrate is performed in a chamber different from the chamber where the group III₂-N layer is deposited. Between the group III₂-N layer deposition and the group III₃-N layer deposition, one or more surface treatment processes are performed on the substrate to reduce non-radiative recombination at the interface and improve overall electroluminescence of the produced structure.

### CROSS-REFERENCE TO RELATED APPLICATIONS

This application claims benefit of U.S. Provisional Patent Application Ser. No. 61/249,470 (APPM/014457L), filed Oct. 7, 2009, which is herein incorporated by reference.

### BACKGROUND OF THE INVENTION

1. Field of the Invention

Embodiments of the present invention generally relate to the manufacturing of devices, such as light emitting diodes (LEDs), laser diodes (LDs) and, more particularly, to processes for forming Group III-V materials by metal-organic chemical vapor deposition (MOCVD) and hydride vapor phase epitaxial (HVPE) deposition processes.

2. Description of the Related Art

Group III-V films are finding greater importance in the development and fabrication of a variety of semiconductor devices, such as short wavelength LEDs, LDs, and electronic devices including high power, high frequency, high temperature transistors and integrated circuits. For example, short wavelength (e.g., blue/green to ultraviolet) LEDs are fabricated using the Group III-nitride semiconducting material gallium nitride (GaN). It has been observed that short wavelength LEDs fabricated using GaN can provide significantly greater efficiencies and longer operating lifetimes than short wavelength LEDs fabricated using non-nitride semiconducting materials, comprising Group II-VI elements.

One method that has been used for depositing Group III-nitrides, such as GaN, is metal organic chemical vapor deposition (MOCVD). This chemical vapor deposition method is generally performed in a reactor having a temperature controlled environment to assure the stability of a first precursor gas which contains at least one element from Group III, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursors react at the surface of the heated substrate to form a Group III-nitride layer on the substrate surface. The quality of the film depends in part upon deposition uniformity which, in turn, depends upon uniform flow and mixing of the precursors across the substrate.

In addition, multichamber processes have certain advantages in forming the film stacks required for LD and LED fabrication. However, the growth interruption experienced during transfer between chambers may lead to reduction of electroluminescence. Thus, there is a need for improved multichamber processes for LD and LED fabrication.

### SUMMARY OF THE INVENTION

In one embodiment, a method for fabricating a compound nitride semiconductor structure comprises flowing a first group-III precursor and a first nitrogen containing precursor into a first processing chamber to deposit a first layer over an existing layer disposed on one or more substrates, transferring the one or more substrates into a second substrate processing chamber without exposing the one or more substrates to atmosphere, performing a surface treatment on the one or more substrates to remove a portion of the first layer, and flowing a second group-III precursor and a second nitrogen containing precursor into the second processing chamber to deposit a second layer over the first layer.

In another embodiment, a method for fabricating a compound nitride semiconductor structure comprises flowing a first group-III precursor and a first nitrogen containing precursor into a first processing chamber to deposit a first layer over an existing layer disposed on one or more substrates, performing a surface treatment on the one or more substrates to at least partially passivate the first layer, transferring the one or more substrates into a second substrate processing chamber without exposing the one or more substrates to atmosphere, and flowing a second group-III precursor and a second nitrogen containing precursor into the second processing chamber to deposit a second layer over the first layer.

In yet another embodiment, a method for fabricating a compound nitride semiconductor structure comprises flowing a first group-III precursor and a first nitrogen containing precursor into a first processing chamber to deposit a first layer over an existing layer disposed on one or more substrates, flowing a p-type dopant over the first layer to lightly dope the surface of the first layer, transferring the one or more substrates into a second substrate processing chamber without exposing the one or more substrates to atmosphere, and flowing a second group-III precursor and a second nitrogen containing precursor into the second processing chamber to deposit a second layer over the first layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic illustration of a structure of a GaN-based LED.

FIG. 1B is a schematic illustration of a GaN based LD structure.

FIG. 2A is a schematic top view illustrating one embodiment of a processing system for fabricating compound nitride semiconductor devices according to embodiments described herein.

FIG. 2B is a schematic top view illustrating another embodiment of a processing system for fabricating compound nitride semiconductor devices according to embodiments described herein.

FIG. 3 is a schematic cross-sectional view of a metal-organic chemical vapor deposition (MOCVD) chamber for fabricating compound nitride semiconductor devices according to embodiments described herein.

FIG. 4 is a schematic cross-sectional view of a hydride vapor phase epitaxy (HVPE) apparatus for fabricating compound nitride semiconductor devices according to embodiments described herein.

FIG. 5 is a flow diagram of a process that may be used for multiple chamber compound nitride semiconductor formation according to embodiments described herein.

FIG. 6 is a flow diagram of another process that may be used for multiple chamber compound nitride semiconductor formation according to embodiments described herein.

### DETAILED DESCRIPTION

Embodiments described herein generally relate to methods for forming Group III-V materials by metal-organic chemical vapor deposition (MOCVD) processes and/or hydride vapor phase epitaxial (HVPE) processes. In one embodiment, deposition of a group III₁-N layer on a substrate is performed in a first chamber, deposition of a group III₂-N layer on the substrate is performed in a second chamber, and deposition of a group III₃-N layer on the substrate is performed in a chamber different from the chamber where the group III₂-N layer is deposited. Between the group III₂-N layer deposition and the group III₃-N layer deposition, one or more surface treatment processes are performed on the substrate to reduce non-radiative recombination at the interface and improve overall electroluminescence of the produced structure. In one embodiment a high temperature GaN layer is deposited in a first processing chamber, an InGaN multiquantum well (MQW) is deposited in a separate processing chamber, and a p-GaN growth process is performed in a processing chamber separate from the processing chamber where the InGaN multi-quantum well (MQW) layer is deposited. After the InGaN MQW layer is deposited, a surface treatment is performed on the InGaN MQW layer prior to growing the p-GaN layer. Exemplary surface treatments may include one or more of a passivation treatment to the InGaN MQW layer prior to transfer to the separate chamber for the p-GaN, a surface removal treatment on the InGaN MQW layer and/or the passivation layer after transfer to the separate chamber for the p-GaN growth, and light doping of a last barrier in the InGaN MQW layer and growth of a p-AlGaN layer on top of the last barrier prior to transfer to the separate chamber for the p-GaN growth.

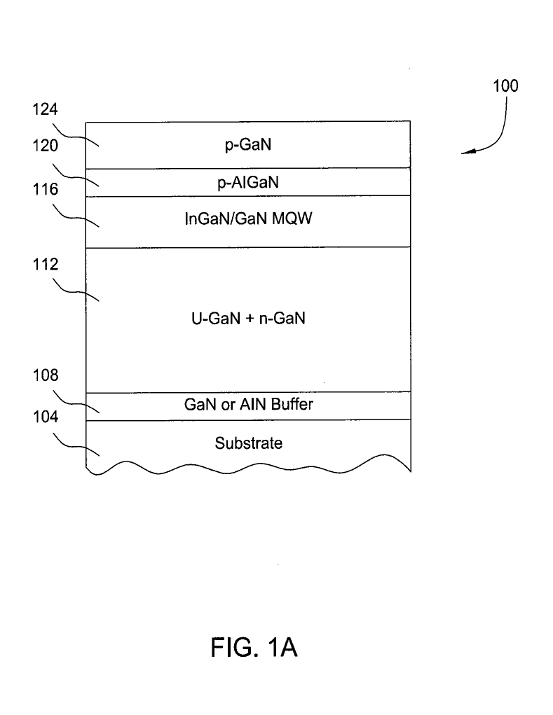

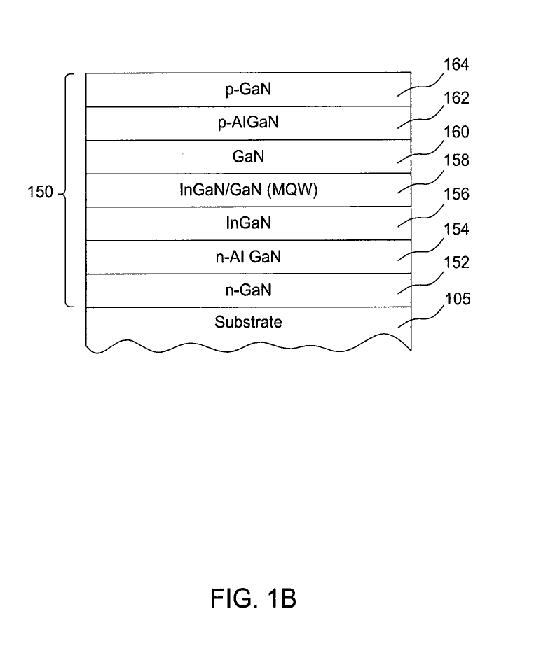

Currently, Metal Organic Chemical Vapor Deposition (MOCVD) techniques are the most widely used techniques for the growth of Group III-nitride based LED manufacturing. One typical nitride-based structure is illustrated in FIG. 1A as a GaN-based LED structure 100. It is fabricated over a substrate 104. Exemplary substrates include sapphire and silicon substrates. A u-GaN followed by an n-type GaN layer 112 is deposited over a GaN or aluminum nitride (AIN) buffer layer 108 formed over the substrate. An active region of the device is embodied in a multi-quantum-well (MQW) layer 116, shown in the drawing as an InGaN/GaN MQW layer. In one embodiment, the InGaN MQW layer 116 includes of stacked pairs of InGaN and GaN bound by GaN barrier layers. A p-n junction is formed with an overlying p-type AlGaN layer 120, with a p-type GaN layer 124 acting as a contact layer.

A typical fabrication process for such an LED may use a metalorganic chemical-vapor-deposition (“MOCVD”) process that follows cleaning of the substrate 104 in a processing chamber. The MOCVD deposition is accomplished by providing flows of suitable precursors to the processing chamber and using thermal processes to achieve deposition. For example, a GaN layer may be deposited using Ga and nitrogen containing precursors, perhaps with a flow of a carrier gas like N₂, H₂, or NH₃. An InGaN layer may be deposited using Ga, N, and In precursors, perhaps with a flow of a carrier gas. The InGaN MQW layer 116 may include of 10 or more stacked pairs of InGaN and GaN bound by GaN barrier layers. An AlGaN layer may be deposited using Ga, N, and Al precursors, also perhaps with a flow of a carrier gas. The GaN buffer layer 108 may have a thickness of between about 200 Å and about 500 Å, and may have been deposited at a temperature of about 550° C. Subsequent deposition of the u-GaN and n-GaN layer 112 is typically performed at a higher temperature, such as around 1050° C. The u-GaN and n-GaN layer 112 may be relatively thick, with deposition of a thickness on the order of 4 μm requiring about 140 minutes for deposition. In one example, the u-GaN and n-GaN layer 112 is 10 μm or greater in order to improve crystal quality, reduce threading dislocation density, and reduce strain energy in the subsequent InGaN MQW layer 116. The InGaN MQW layer 116 may have a thickness of between about 100 Å and about 1000 Å, which may be deposited over a period of about 40 minutes at a temperature of about 750° C. The p-AlGaN layer 120 may have a thickness of between about 200 Å and about 600 Å, which may be deposited in about five minutes at a temperature from about 950° C. to about 1020° C. The thickness of the p-type GaN layer 124 or contact layer that completes the structure may be between about 0.1 μm and about 0.5 μm and may be deposited at a temperature of about 1020° C. for around 25 minutes. Additionally, dopants, such as silicon (Si) or magnesium (Mg), may be added to the films. The films may be doped by adding small amounts of dopant gases during the deposition process. For silicon, or n-type, doping, silane (SiH₄) or disilane (Si₂H₆) gases may be used, for example, and a dopant gas may include Bis(cyclopentadienyl) magnesium (Cp₂Mg or (C₅H₅)₂Mg) for magnesium (Mg), or p-type, doping.

FIG. 1B is a schematic illustration of a GaN based LD structure 150 formed on an aluminum oxide containing substrate 105, such as a sapphire or silicon substrate. The LD structure 150 may be formed on the substrate 105 after a thermal cleaning procedure and a pretreatment process. The thermal cleaning procedure may be performed by exposing the substrate 105 to a cleaning gas mixture comprising ammonia and carrier gas while the substrate 105 is being heated. The pretreatment process may include exposing the substrate to a pretreatment gas mixture while the substrate is heated in an elevated temperature range. In one example, the pretreatment gas mixture is an etchant, such as a halogen gas.

The LD structure 150 is a stack formed on the substrate 105. The LD structure 150 starts from an n-type GaN contact layer 152. The LD structure 150 further comprises an n-type cladding layer 154. The cladding layer 154 may comprise AlGaN. An undoped guide layer 156 is formed over the cladding layer 154. The guide layer 156 may comprise InGaN. An active layer 158 having a multiquantum well (MQW) structure is formed on the guide layer 156. In one example, the active layer 158 comprises 10 or more stacked pairs of InGaN and GaN bound by GaN barrier layers. An undoped guide layer 160 is formed over the active layer 158. A p-type electron block layer 162 is formed over the undoped guide layer 160. A p-type contact GaN layer 164 is formed over the p-type electron block layer 162.

In certain processes, the aforementioned steps are performed in a single MOCVD chamber, i.e., there is no growth interruption during the growth of the different layers. However, the growth of GaN at high temperatures results in severe parasitic deposition of Ga metal and GaN within the MOCVD chamber, especially on chamber components including the showerhead or gas distribution assembly of the MOCVD chamber. Additionally, in single chamber processes, there is a risk of cross-contamination between the In of the MQW layer and the p-type dopant, such as Mg. In certain embodiments having cluster-type or in-line tools, full growth of LEDs or LDs may be performed in separate chambers without a break from a vacuum environment between processes. Several advantages exist with respect to multi-chamber processes as compared to single chamber processes. For instance, the risk of cross-contamination is reduced, and the InGaN MQW layer is not affected by the severe showerhead coating which occurs during high temperature GaN growth. However, with the growth interruption before and after the MQW layer deposition, the overall electroluminescence of a split LED may be reduced by 20-80% or more compared with an in situ LED grown by a single chamber. This reduction may be attributed to the phenomenon of surface recombination, more specifically, non-radiative recombination that occurs in the interface between the MQW and p-AlGaN layers. Surface reconstruction may occur during the growth break between the MQW and p-AlGaN layers due to dangling bonds rearranging and forming bonds with neighboring atoms. This may lead to new atomic structures being formed locally with surface energies different from bulk atomic states. Such surface recombination may lead to increased heating of the surface due to non-radiative recombination at the interface, resulting in significantly reduced luminescence efficiency.

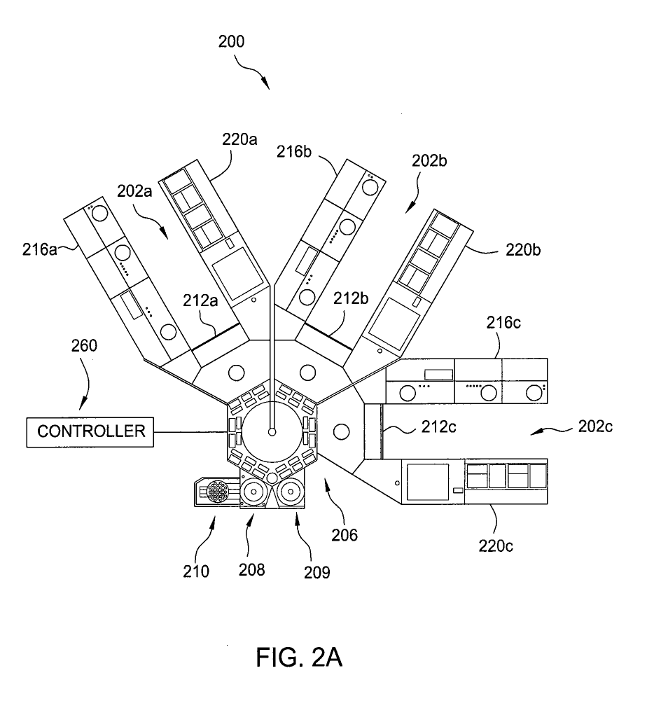

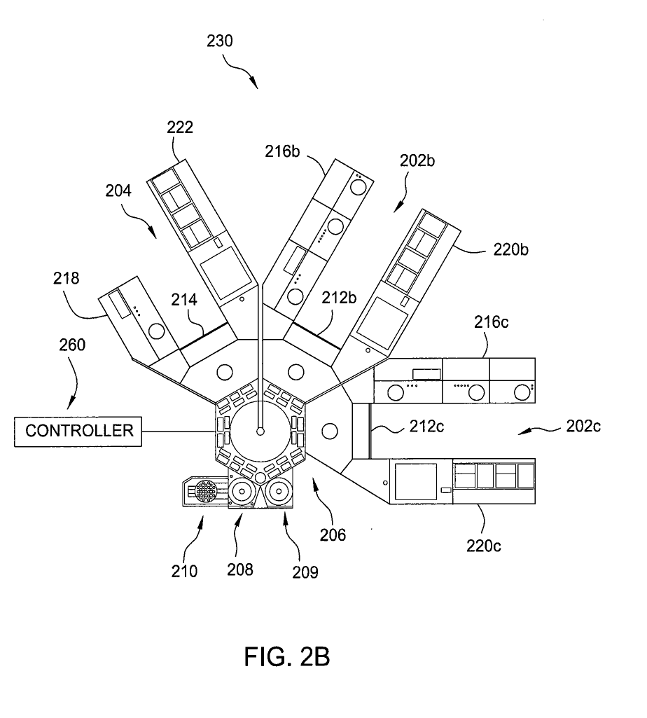

FIG. 2A is a schematic top view illustrating one embodiment of a processing system 200 comprising multiple MOCVD chamber 202a, 202b, 202c for fabricating compound nitride semiconductor devices according to embodiments described herein. The environment within the processing system 200 is maintained as a vacuum environment or at a pressure below atmospheric pressure. It may be desirable to backfill the processing system 200 with an inert gas such as nitrogen. Although three MOCVD chambers 202a, 202b, 202c are shown, it should be understood that any number of MOCVD chambers or additionally, combinations of one or more MOCVD chambers with one or more Hydride Vapor Phase Epitaxial (HVPE) chambers may also be coupled with the transfer chamber 206.

Each MOCVD chamber 202a, 202b, 202c comprises a chamber body 212a, 212b, 212c forming a processing region where a substrate is placed to undergo processing, a chemical delivery module 216a, 216b, 216c from which gas precursors are delivered to the chamber body 212a, 212b, 212c, and an electrical module 220a, 220b, 220c for each MOCVD chamber 202a, 202b, 202c that includes the electrical system for each MOCVD chamber of the processing system 200. Each MOCVD chamber 202a, 202b, 202c is adapted to perform CVD processes in which metalorganic elements react with metal hydride elements to form thin layers of compound nitride semiconductor materials.

The processing system 200 comprises a transfer chamber 206 housing a substrate handler (not shown), a first MOCVD chamber 202a, a second MOCVD chamber 202b, and a third MOCVD chamber 202c coupled with the transfer chamber 206, a loadlock chamber 208 coupled with the transfer chamber 206, a batch loadlock chamber 209, for storing substrates, coupled with the transfer chamber 206, and a load station 210, for loading substrates, coupled with the loadlock chamber 208. The transfer chamber 206 comprises a robot assembly (not shown) operable to pick up and transfer substrates between the loadlock chamber 208, the batch loadlock chamber 209, and the MOCVD chamber 202.

The transfer chamber 206 may remain under vacuum and/or at a pressure below atmosphere during the process. The vacuum level of the transfer chamber 206 may be adjusted to match the vacuum level of the MOCVD chamber 202a. For example, when transferring a substrate from a transfer chamber 206 into the MOCVD chamber 202a (or vice versa), the transfer chamber 206 and the MOCVD chamber 202a may be maintained at the same vacuum level. Then, when transferring a substrate from the transfer chamber 206 to the load lock chamber 208 or batch load lock chamber 209 (or vice versa), the transfer chamber vacuum level may match the vacuum level of the loadlock chamber 208 or batch load lock chamber 209 even through the vacuum level of the loadlock chamber 208 or batch load lock chamber 209 and the MOCVD chamber 202a may be different. Thus, the vacuum level of the transfer chamber may be adjusted. It may be desirable to backfill the transfer chamber 206 with an inert gas such as nitrogen. For example, the substrate the transferred in an environment having greater than 90% N₂. In another example, the substrate is transferred in a high purity NH₃ environment, such as an environment having greater than 90% NH₃. In yet another example, the substrate is transferred in a high purity H₂ environment, such as an environment having greater than 90% H₂.

In the processing system 200, the robot assembly transfers a carrier plate under vacuum loaded with substrates into the first MOCVD chamber 202a to undergo a first deposition process. The robot assembly transfers the carrier plate under vacuum into the second MOCVD chamber 202b to undergo a second deposition process. The robot assembly transfers the carrier plate under vacuum into either the first MOCVD chamber 202a or the third MOCVD chamber 202c to undergo a third deposition process. After all or some of the deposition steps have been completed, the carrier plate is transferred from the MOCVD chamber 202a-c back to the loadlock chamber 208. In one embodiment, the carrier plate is then released toward the load station 210. In another embodiment, the carrier plate may be stored in either the loadlock chamber 208 or the batch load lock chamber 209 prior to further processing in the MOCVD chamber 202a-c. One exemplary system is described in U.S. patent application Ser. No. 12/023,572, filed Jan. 31, 2008, entitled PROCESSING SYSTEM FOR FABRICATING COMPOUND NITRIDE SEMICONDUCTOR DEVICES, which is hereby incorporated by reference in its entirety.

A system controller 260 controls activities and operating parameters of the processing system 200. The system controller 260 includes a computer processor and a computer-readable memory coupled to the processor. The processor executes system control software, such as a computer program stored in memory. Aspects of the processing system and methods of use are further described in U.S. patent application Ser. No. 11/404,516, filed Apr. 14, 2006, now published as US 2007-024,516, titled EPITAXIAL GROWTH OF COMPOUND NITRIDE STRUCTURES, which is hereby incorporated by reference in its entirety.

FIG. 2B is a schematic top view illustrating another embodiment of a processing system 230 for fabricating compound nitride semiconductor devices according to embodiments described herein. Similar to the processing system 200 depicted in FIG. 2A, the processing system 230 comprises a second MOCVD chamber 202b and a third MOCVD chamber 202c, however, unlike the processing system 200 depicted in FIG. 2A, the processing system 230 replaces the first MOCVD chamber 202a with a HVPE chamber 204. The HVPE chamber 204 is adapted to perform HVPE processes in which gaseous metal halides are used to epitaxially grow thick layers of compound nitride semiconductor materials on heated substrates. The HVPE chamber 204 comprises a chamber body 214 where a substrate is placed to undergo processing, a chemical delivery module 218 from which gas precursors are delivered to the chamber body 214, and an electrical module 222 that includes the electrical system for the HVPE chamber of the processing system 230.

In the processing system 230, the robot assembly transfers a carrier plate under vacuum loaded with substrates into the HVPE chamber 204 to undergo a first deposition process. The robot assembly transfers the carrier plate under vacuum into the second MOCVD chamber 202b to undergo a second deposition process. The robot assembly transfers the carrier plate under vacuum into the third MOCVD chamber 202c to undergo a third deposition process.

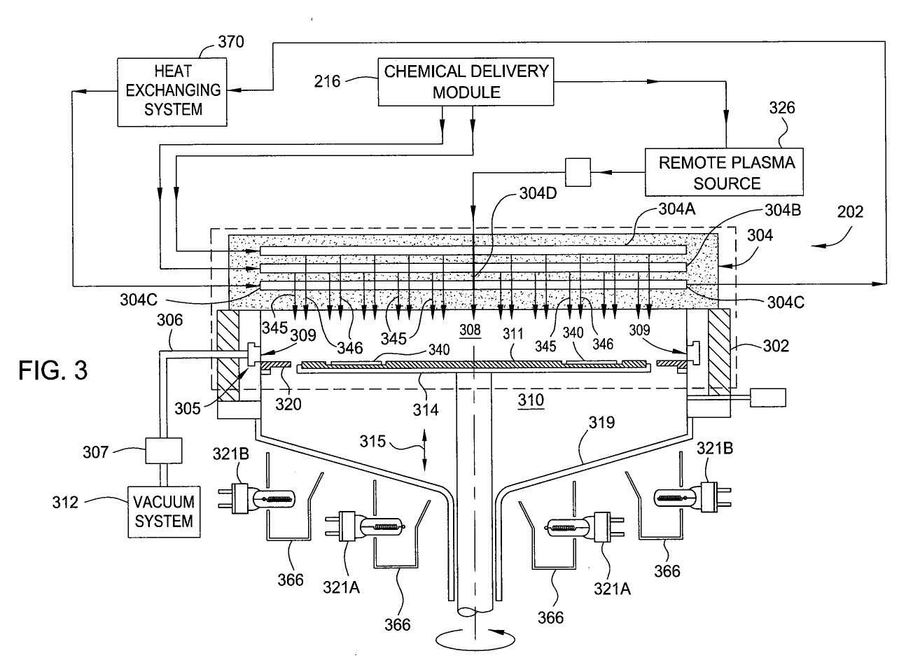

FIG. 3 is a schematic cross-sectional view of an MOCVD chamber 202 according to embodiments described herein. The MOCVD chamber 202 comprises a chamber body 302, a chemical delivery module 216 for delivering precursor gases, carrier gases, cleaning gases, and/or purge gases, a remote plasma system 326 with a plasma source, a susceptor or substrate support 314, and a vacuum system 312. The chamber body 302 encloses a processing volume 308. A showerhead assembly 304 is disposed at one end of the processing volume 308, and a carrier plate 311 is disposed at the other end of the processing volume 308. The carrier plate 311 may be disposed on the substrate support 314. The substrate support 314 has capability for moving in a vertical direction, as shown by arrow 315. The vertical lift capability may be used to move the substrate support 314 either upward and closer to the showerhead assembly 304 or downward and further away from the showerhead assembly 304. In certain embodiments, the substrate support 314 comprises a heating element, for example, a resistive heating element (not shown) for controlling the temperature of the substrate support 314 and consequently controlling the temperature of the carrier plate 311 and substrates 340 positioned on the substrate support 314.

The showerhead assembly 304 has a first processing gas channel 304A coupled with the chemical delivery module 216 for delivering a first precursor or first process gas mixture to the processing volume 308, a second processing gas channel 304B coupled with the chemical delivery module 216 for delivering a second precursor or second process gas mixture to the processing volume 308 and a temperature control channel 304C coupled with a heat exchanging system 370 for flowing a heat exchanging fluid to the showerhead assembly 304 to help regulate the temperature of the showerhead assembly 304. Suitable heat exchanging fluids include but are not limited to water, water-based ethylene glycol mixtures, a perfluoropolyether (e.g. Galden® fluid), oil-based thermal transfer fluids, or similar fluids. During processing the first precursor or first process gas mixture may be delivered to the processing volume 308 via gas conduits 346 coupled with the first processing gas channel 304A in the showerhead assembly 304 and the second precursor or second process gas mixture may be delivered to the processing volume 308 via gas conduits 345 coupled with the second gas processing channel 304B. Where the remote plasma source is used, the plasma may be delivered to the processing volume 308 via conduit 304D. It should be noted that the process gas mixtures or precursors may comprise one or more precursor gases or process gases as well as carrier gases and dopant gases which may be mixed with the precursor gases.

Exemplary showerheads that may be adapted to practice embodiments described herein are described in U.S. patent application Ser. No. 11/873,132, filed Oct. 16, 2007, now published as US 2009-0098276, entitled MULTI-GAS STRAIGHT CHANNEL SHOWERHEAD, U.S. patent application Ser. No. 11/873,141, filed Oct. 16, 2007, now published as US 2009-0095222, entitled MULTI-GAS SPIRAL CHANNEL SHOWERHEAD, and U.S. patent application Ser. No. 11/873,170, filed Oct. 16, 2007, now published as US 2009-0095221, entitled MULTI-GAS CONCENTRIC INJECTION SHOWERHEAD, all of which are incorporated by reference in their entireties.

A lower dome 319 is disposed at one end of a lower volume 310, and the carrier plate 311 is disposed at the other end of the lower volume 310. The carrier plate 311 is shown in process position, but may be moved to a lower position where, for example, the substrates 340 may be loaded or unloaded. An exhaust ring 320 may be disposed around the periphery of the carrier plate 311 to help prevent deposition from occurring in the lower volume 310 and also help direct exhaust gases from the chamber 202 to exhaust ports 309. The lower dome 319 may be made of transparent material, such as high-purity quartz, to allow light to pass through for radiant heating of the substrates 340. The radiant heating may be provided by a plurality of inner lamps 321A and outer lamps 321B disposed below the lower dome 319 and reflectors 366 may be used to help control the chamber 203 exposure to the radiant energy provided by inner and outer lamps 321A, 321B. Additional rings of lamps may also be used for finer temperature control of the substrates 340.

A purge gas (e.g., a nitrogen containing gas) may be delivered into the chamber 202 from the showerhead assembly 304 and/or from inlet ports or tubes (not shown) disposed below the carrier plate 311 and near the bottom of the chamber body 302. The purge gas enters the lower volume 310 of the chamber 202 and flows upwards past the carrier plate 311 and exhaust ring 320 and into multiple exhaust ports 309 which are disposed around an annular exhaust channel 305. An exhaust conduit 306 connects the annular exhaust channel 305 to a vacuum system 312 which includes a vacuum pump 307. The chamber 202 pressure may be controlled using a valve system which controls the rate at which the exhaust gases are drawn from the annular exhaust channel. Other aspects of the MOCVD chamber 203 are described in U.S. patent application Ser. No. 12/023,520, filed Jan. 31, 2008, and titled CVD APPARATUS, which is herein incorporated by reference in its entirety.

A cleaning gas (e.g., a halogen gas) may be delivered into the chamber 202 from the showerhead assembly 304 and/or from inlet ports or tubes (not shown) disposed near the processing volume 308. The cleaning gas enters the processing volume 308 of the chamber 202 to remove deposits from chamber components such as the substrate support 314 and the showerhead assembly 304 and exits the chamber via multiple exhaust ports 309 which are disposed around the annular exhaust channel 305.

The chemical delivery module 216 supplies chemicals to the MOCVD chamber 203. Reactive gases, carrier gases, purge gases, and cleaning gases are supplied from the chemical delivery system through supply lines and into the chamber 203. In one embodiment, the gases are supplied through supply lines and into a gas mixing box where they are mixed together and delivered to showerhead 304. In another embodiment, the gases are delivered to the showerhead 304 through separate supply lines and mixed within the chamber 202. Generally supply lines for each of the gases include shut-off valves that can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback, backpressure regulators may be included to control precursor gas concentrations, valve switching control may be used for quick and accurate valve switching capability, moisture sensors in the gas lines measure water levels and can provide feedback to the system software which in turn can provide warnings/alerts to operators. The gas lines may also be heated to prevent precursors and cleaning gases from condensing in the supply lines. Depending upon the process used some of the sources may be liquid rather than gas. When liquid sources are used, the chemical delivery module includes a liquid injection system or other appropriate mechanism (e.g. a bubbler) to vaporize the liquid. Vapor from the liquids is then usually mixed with a carrier gas as would be understood by a person of skill in the art.

Remote plasma system 326 can produce plasma for selected applications, such as chamber cleaning or etching residue from a process substrate. The remote plasma system 326 may be a remote microwave plasma system. Plasma species produced in the remote plasma system 326 from precursors supplied via an input line are sent via a conduit for dispersion through the showerhead assembly 304 to the MOCVD chamber 202. Precursor gases for a cleaning application may include chlorine containing gases, fluorine containing gases, iodine containing gases, bromine containing gases, nitrogen containing gases, and/or other reactive elements. Remote plasma system 326 may also be adapted to deposit CVD layers flowing appropriate deposition precursor gases into remote plasma system 326 during a layer deposition process. The remote plasma system 326 may used to deliver active nitrogen species to the processing volume 308.

The temperature of the walls of the MOCVD chamber 202 and surrounding structures, such as the exhaust passageway, may be further controlled by circulating a heat-exchange liquid through channels (not shown) in the walls of the chamber. The heat-exchange liquid can be used to heat or cool the chamber walls depending on the desired effect. For example, hot liquid may help maintain an even thermal gradient during a thermal deposition process, whereas a cool liquid may be used to remove heat from the system during an in-situ plasma process, or to limit formation of deposition products on the walls of the chamber. The showerhead assembly 304 may also have heat exchanging passages (not shown). Typical heat-exchange fluids water-based ethylene glycol mixtures, oil-based thermal transfer fluids, or similar fluids. This heating, referred to as heating by the “heat exchanger”, beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

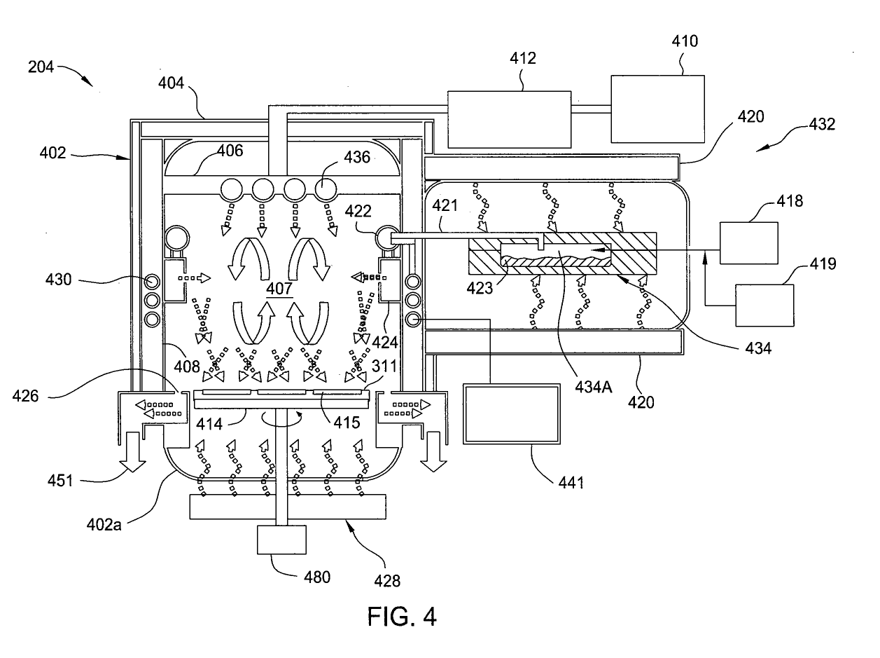

FIG. 4 is a schematic sectional view of an HVPE chamber 204 for fabricating compound nitride semiconductor devices according to embodiments described herein. The HVPE chamber 204 includes a chamber body 402 enclosed by a lid 404. The chamber body 402 and the lid 404 define a processing volume 407. A showerhead 406 is disposed in an upper region of the processing volume 407. A susceptor 414 is disposed opposing the showerhead 406 in the processing volume 407. The susceptor 414 is configured to support a plurality of substrates 415 thereon during processing. The plurality of substrates 415 is disposed on a carrier plate 311 which is supported by the susceptor 414. The susceptor 414 may be rotated by a motor 480, and may be formed from a variety of materials, including SiC or SiC-coated graphite. In one example, the susceptor 414 may be rotated at about 2 RPM to about 100 RPM, such as at about 30 RPM. Rotating the susceptor 414 aids in providing uniform exposure of the processing gases to each substrate.

The HVPE chamber 204 comprises a heating assembly 428 configured to heat the substrates 415 on the susceptor 414. The chamber bottom 402a may be formed from quartz, and the heating assembly 428 may be a lamp assembly disposed under the chamber bottom 402a to heat the substrates 415 through the quartz chamber bottom 402a. In one example, the heating assembly 428 comprises an array of lamps that are distributed to provide a uniform temperature distribution across the substrates, substrate carrier, and/or susceptor.

The HVPE chamber 204 further comprises a precursor supplying pipes 422, 424 disposed inside the side wall 408 of the chamber 402. The pipes 422 and 424 are in fluid communication with the processing volume 407 and an inlet tube 421 found in a precursor source module 432. The showerhead 406 is in fluid communication with the processing volume 407 and a gas source 410. The processing volume 407 is in fluid communication with an exhaust 451 via an annular port 426.

The HVPE chamber 204 further comprises a heater 430 embedded within the walls 408 of the chamber body 402. The heater elements 430 embedded in the walls 408 may provide additional heat if needed during the deposition process. A thermocouple may be used to measure the temperature inside the processing chamber. Output from the thermocouple may be fed back to a controller 441 that controls the temperature of the walls of the chamber body 402 by adjusting the power delivered to the heater elements 430 (e.g., resistive heating elements) based upon the reading from a thermocouple (not shown). For example, if the chamber is too cool, the heater 430 will be turned on. If the chamber is too hot, the heater 430 will be turned off. Additionally, the amount of heat provided from the heater 430 may be controlled so that the amount of heat is provided from the heater 430 is minimized.

Processing gas from the gas source 410 is delivered to the processing volume 407 through a gas plenum 436 disposed in the gas distribution showerhead 406. The gas source 410 may comprise a nitrogen containing compound. In one example, the gas source 410 is configured to deliver a gas that comprises ammonia or nitrogen. An inert gas such as helium or diatomic nitrogen may be introduced as well either through the gas distribution showerhead 406 or through the pipe 424, disposed on the walls 408 of the chamber 402. An energy source 412 may be disposed between the gas source 410 and the gas distribution showerhead 406. The energy source 412 may include a heater or a remote RF plasma source. The energy source 412 may provide energy to the gas delivered from the gas source 410, so that radicals or ions can be formed, so that the nitrogen in the nitrogen containing gas is more reactive.

The source module 432 comprises a halogen gas source 418 connected to a well 434A of a source boat 434 and an inert gas source 419 connected to the well 434A. A source material 423, such as aluminum, gallium or indium is disposed in the well 434A. A heating source 420 surrounds the source boat 434. An inlet tube 421 connects the well 434A to the processing volume 407 via the pipes 422, 424.

During processing a halogen gas (e.g., Cl₂, Br₂, or I₂) may be delivered from the halogen gas source 418 to the well 434A of the source boat 434 to create a metal halide precursor (e.g., GaCl, GaCl₃, AlCl₃). The interaction of the halogen gas and the solid or liquid source material 423 allows a metal halide precursor to be formed. The source boat 434 may be heated by the heating source 420 to heat the source material 423 and allow the metal halide precursor to be formed. The metal halide precursor is then delivered to the processing volume 407 of the HVPE chamber 204 through an inlet tube 421. An inert gas (e.g., Ar, N₂) delivered from the inert gas source 419 may carry, or push, the metal halide precursor formed in the well 434A through the inlet tube 421 and pipes 422 and 424 to the processing volume 407 of the HVPE chamber 204. A nitrogen-containing precursor gas (e.g., ammonia (NH₃), N₂) may be introduced into the processing volume 407 through the showerhead 406, while the metal halide precursor is also provided to the processing volume 407, so that a metal nitride layer can be formed on the surface of the substrates 415 disposed in the processing volume 407.

### Multiple Chamber Process:

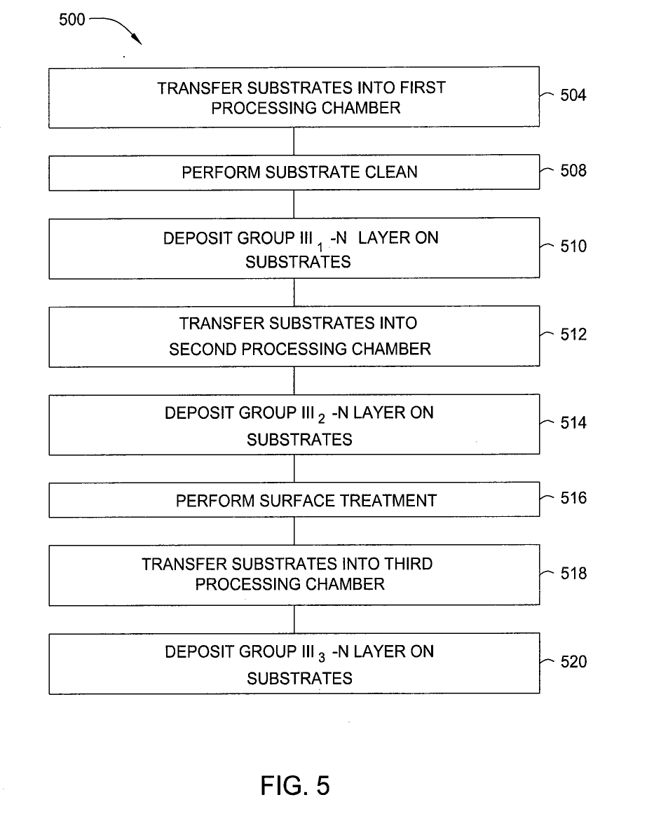

FIG. 5 is a flow diagram of a process 500 that may be used for multiple chamber compound nitride semiconductor formation according to embodiments described herein. The process begins at block 504 by transferring one or more substrates into a first substrate processing chamber. The first substrate processing chamber may be an MOCVD chamber or an HVPE chamber as described above. For deposition of a nitride structure, the one or more substrates may comprise sapphire, although other materials that may be used include SiC, Si, spinel, lithium gallate, ZnO, and others. The one or more substrates are cleaned at block 508, after which the one or more substrates may be cooled in a nitrogen rich environment. Next, process parameters suitable for growth of a nitride layer are established. Such process parameters may include temperature, pressure, and the like to define an environment within the processing chamber appropriate for thermal deposition of a nitride layer. Flows of precursors are provided on the one or more substrates to deposit III₁-N structures on the one or more substrates at block 510. The III₁-N structures may be deposited to a thickness of 10 μm or more to improve crystal quality, reduce threading dislocation density, and reduce strain energy in subsequently deposited layers. The precursors may include a nitrogen source and a source for a first group-III element such as Ga. In one example, the nitrogen precursor is NH₃. In another example, the nitrogen source may be one or more active nitrogen species derived from remote plasma of a nitrogen-containing material such as nitrogen gas (N₂), nitrous oxide (N₂O), ammonia (NH₃), hydrazine (N₂H₄), diimide (N₂H₂), hydrazoic acid (HN₃), and the like. The flow rate of the nitrogen source may be between about 3000 sccm to about 9000 sccm. A suitable Ga precursor includes, for example, trimethyl gallium (“TMG”). The first group-III element may comprise a plurality of distinct group-III elements such as Al and Ga, in which case a suitable Al precursor may be trimethyl aluminum (“TMA”). In another example, the plurality of distinct group-III elements includes In and Ga, in which case a suitable In precursor may be trimethyl indium (“TMI”). A flow of one or more carrier gases selected from the group of argon, nitrogen, hydrogen, helium, neon, xenon, and combinations thereof may also be included.

After deposition of the III₁-N structure at block 510, the precursor flows are terminated. The nitrogen precursor may be continued during cool down of the one or more substrates. The one or more substrates are removed from the processing chamber without exposing the substrate to atmosphere and transferred under vacuum to a second processing chamber at block 512. Transferring the substrate from the processing chamber without braking vacuum prevents exposure of the deposited III₁-N structure to oxygen and carbon, which act as electrically active dopants/impurities. The second substrate processing chamber may be a MOCVD chamber as described above.

In one embodiment, prior to transfer to the second processing chamber, a surface treatment to passivate dangling bonds on the surface of the III₁-N layer is performed at elevated temperatures, such as from about 500° C. to about 1200° C. Preferably, the surface treatment is performed from about 700° C. to about 1000° C. The surface may be passivated by flowing precursor gases over the surface of the substrate, such as a magnesium, gallium, indium, or aluminum precursor. A suitable magnesium precursor may be Cp₂Mg. A suitable gallium precursor may be TMG. A suitable indium precursor may be TMI. A suitable aluminum precursor may be TMA. The passivation treatment may be performed while flowing a nitrogen containing precursor, such as ammonia.

After the substrate is transferred into the second processing chamber at block 512, subsequent deposition steps are performed in the second processing chamber. In one embodiment, a surface treatment using H₂, NH₃, or a halogen based etching gas (e.g., chlorine based gas, fluorine based gas) is performed at elevated temperatures, such as from about 500° C. to about 1200° C. In one example, this treatment partially removes one or more atomic layers of the III₁-N layer. In another example, this treatment removes the passivation layer deposited over the III₁-N layer in the first processing chamber.

After the substrate is transferred into the second processing chamber at block 512, an additional III₁-N layer is grown on the one or more substrates at block 514. At block 514, process parameters suitable for growth of a III₂-N layer are first established. Such process parameters may include temperature, pressure, and the like to define an environment within the processing chamber appropriate for thermal deposition of a nitride layer. Flows of precursors are then provided on the one or more substrates to deposit III₂-N structures on the substrate at block 514. The III₂-N structures may be deposited in thin layers to form an MQW layer.

The III₂-N structure may include a group-III element that is not included in the III₁-N layer, although the III₁-N and III₂-N layers may additionally comprise a common group-III element. For instance, in the case where the III₁-N layer is GaN, the III₂-N layer may be an AlGaN layer or an InGaN layer. While these are examples in which the III₂-N layer has a ternary composition, this is not required and the III₂ layer may more generally include such other compositions as quaternary AlInGaN layers. Similarly, in embodiments where the III₁-N layer is AlGaN, the III₂-N layer may be an InGaN layer on an AlInGaN layer. Suitable precursors for deposition of the III₂-N layer may be similar to the precursors used for the III₁-N layer, i.e. NH₃ is a suitable nitrogen precursor, TMG is a suitable gallium precursor, TMA is a suitable aluminum precursor, and TMI is a suitable indium precursor. A flow of one or more carrier gases selected from the group of argon, nitrogen, hydrogen, helium, neon, xenon, and combinations thereof may also be included.

After deposition of the III₂-N structure at block 514, the precursor flows are terminated. In one embodiment, one or more treatment processes are performed on the one or more substrates at block 516. In one embodiment of block 516, the deposition of the III₂-N structure is terminated in a nitrogen-rich environment to at least partially passivate the last barrier by preventing dissociation of ions in the layer. For example, the deposition of the III₂-N structure may be terminated in an environment containing from about 10% to about 90% nitrogen.

In one embodiment of block 516, a surface treatment to passivate dangling bonds on the surface of the III₂-N layer is performed at elevated temperatures, such as from about 500° C. to about 1200° C. Preferably, the surface treatment is performed from about 700° C. to about 1000° C. The surface may be passivated by flowing precursor gases over the surface of the substrate, such as a magnesium, gallium, indium, or aluminum precursor. A suitable magnesium precursor may be Cp₂Mg. A suitable gallium precursor may be TMG. A suitable indium precursor may be TMI. A suitable aluminum precursor may be TMA. The passivation treatment may be performed while flowing a nitrogen containing precursor, such as ammonia.

In another embodiment of block 516, a surface treatment for the III₂-N layer includes lightly doping the last barrier of the layer with a p-type dopant, such as magnesium (Mg), followed by growth of a III₃-N layer. This treatment may help minimize the non-radiative surface recombination of the growth break by passivating donor-type defects or dangling bonds and ensuring that enough holes can enter and be recombined in the III₂-N layer, thus increasing the luminescence efficiency of the device.

The one or more substrates are removed from the second processing chamber without exposing the one or more substrates to atmosphere and transferred under vacuum to a third substrate processing chamber at block 518. Transferring the one or more substrates from the processing chamber without breaking vacuum prevents exposure of the deposited III₂-N structure to oxygen and carbon which act as electrically active dopants/impurities. The third substrate processing chamber may be a MOCVD as described above.

After the one or more substrates are transferred into the third processing chamber at block 518, a surface treatment is performed prior to subsequent deposition processes. In one embodiment, a surface treatment using H₂, NH₃, or a halogen based etching gas (e.g., chlorine based gas, fluorine based gas) is performed at elevated temperatures, such as from about 500° C. to about 1200° C. In one example, this treatment partially removes one or more atomic layers of GaN from the surface of the III₂-N layer. In another example, this treatment removes the passivation layer deposited at block 516. In these examples, subsequent regrowth of GaN in the third processing chamber minimizes the dangling bonds or surface reconstruction in the interface resulting in higher luminescence efficiency.

After the one or more substrates are transferred into the third processing chamber at block 518 subsequent deposition steps are performed in the third processing chamber. After the one or more substrates are transferred into the third processing chamber, additional deposition of the III₂-N layer may be performed to prevent the growth break from being at the interface between the III₂-N layer and a III₃-N layer at block 520. Process parameters suitable for growth of the III₃-N layer are first established. Such process parameters may include temperature, pressure, and the like to define an environment within the processing chamber appropriate for thermal deposition of a nitride layer. Flows of III₃ and nitrogen precursors are provided on the substrate to deposit III₃-N structures on the substrate at block 520. The precursor flows are terminated following the deposition. The flow of the nitrogen precursor may be continued during cool down of the one or more substrates.

The processing conditions used for deposition of the III₁-N, the III₂-N, and the III₃-N layers may vary depending on specific applications. The following table provides exemplary processing conditions and precursor flow rates that are generally suitable in the growth of nitride semiconductor structures using the devices described above:

| Parameter | Value |
|---|---|
| Temperature (° C.) | 500-1200 |
| Pressure (Torr) | 5-760 |
| TMG flow (sccm) | 0-50 |
| TMA flow (sccm) | 0-50 |
| TMI flow (sccm) | 0-50 |
| PH₃ flow (sccm) | 0-1000 |
| AsH₃ flow (sccm) | 0-1000 |
| NH₃ flow (sccm) | 100-100,000 |
| N₂ flow (sccm) | 0-100,000 |
| H₂ flow (sccm) | 0-100,000 |
| Cp₂Mg | 0-2,000 |

As will be evident from the preceding description, a process might not use flows of all the precursors in any given process. For example, growth of GaN might use flows of TMG, NH₃, and N₂; growth of AlGaN might use flows of TMG, TMA, NH₃, and H₂, with the relative flow rates of TMA and TMG selected to provide a desired relative Al:Ga stoichiometry of the deposited layer; and growth of InGaN might use flows of TMG, TMI, NH₃, N₂, and H₂, with relative flow rates of TMI and TMG selected to provide a desired relative In:Ga stoichiometry of the deposited layer.

Optionally, a cleaning process may be performed in which the interior of each processing chamber is exposed to a cleaning gas to remove gallium containing deposits from the chamber and chamber components after removal of the substrate from the processing chamber. The cleaning process may comprise exposing the chamber to etchant gases which thermally etch deposition from chamber walls and surfaces. Optionally, the processing chamber may be exposed to plasma during the cleaning process. Cleaning gases for the cleaning process may include halogen containing gases such as fluorine containing gases, chlorine containing gases, iodine containing gases, bromine containing gases, and/or other reactive elements. A flow of one or more carrier gases selected from the group of argon, nitrogen, hydrogen, helium, neon, xenon, and combinations thereof may also be included. The cleaning process may comprise exposing the chamber to plasma. The plasma may be generated by a remote plasma generator. In another example, the plasma is generated in situ. Exemplary cleaning processes which may be used with the embodiments described herein are described in U.S. patent application Ser. No. 12/244,440, filed Oct. 2, 2008, titled METHOD FOR DEPOSITING GROUP III/V COMPOUNDS, and U.S. Provisional Patent Application Ser. No. 61/173,552, filed Apr. 28, 2009, titled MOCVD SINGLE CHAMBER SPLIT PROCESS FOR LED MANUFACTURING, both of which are herein incorporated in their entirety.

### Example

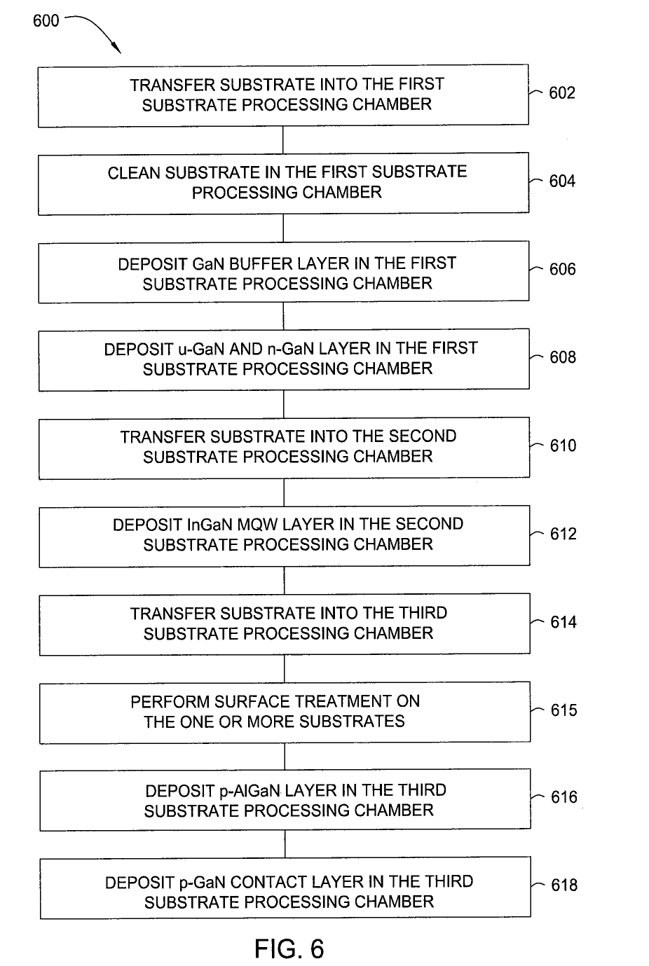

The following example is provided to illustrate how the general process may be used for the fabrication of compound nitride structures described in connection with processing system 200. The example refers to a LED structure, with its fabrication being performed using a processing system 200 having three MOCVD chambers 202. An overview of the process is provided with the flow diagram of FIG. 6 showing a process sequence 600. The deposition of the initial III₁-N layers (e.g., the GaN layers) is performed either in the first MOCVD chamber 202a or the HVPE chamber 204, deposition of III₂-N layers (e.g., the InGaN layer) is performed in the second MOCVD chamber 202b, and deposition of the III₃-N layers (e.g. the AlGaN, and GaN contact layers) is performed in the third MOCVD chamber 202c.

At block 602 one or more sapphire substrates are transferred into the first substrate processing chamber. Where the first substrate processing chamber is an MOCVD chamber, a carrier plate 311 containing one or more substrates 340 is transferred into the first MOCVD chamber 202a. The MOCVD chamber 202a is configured to provide rapid deposition of GaN.

At block 604, the substrate is cleaned in the first substrate processing chamber. The one or more substrates are cleaned by flowing chlorine gas at a flow rate between 200 sccm to about 1000 sccm and ammonia at a flow rate between 500 sccm to about 9000 sccm within a temperature range between about 625° C. to about 1000° C. The one or more substrates are then cooled in a nitrogen rich environment.

At block 606, a pretreatment process and/or buffer layer is grown over the substrate in the MOCVD chamber 202a using MOCVD precursor gases TMG, NH₃, and N₂ at a temperature of about 550° C. and a chamber pressure of about 300 Torr.

This is followed by growth of a thick u-GaN/n-GaN layer, which in this example is performed using MOCVD precursor gases TMG, NH₃, and N₂ at a temperature of about 1050° C. and a chamber pressure of about 300 Torr at block 608. The u-GaN/n-Gan layer is grown to a thickness of 10 μm or greater to improve crystal quality, reduce threading dislocation density, and reduce strain energy in the subsequent MQW layer.

Where the first substrate processing chamber is an HVPE chamber, a carrier plate 311 containing one or more substrates 340 is transferred into the HVPE chamber 204. The HVPE chamber 204 is configured to provide rapid deposition of GaN. At block 606, a pretreatment process and/or buffer layer is grown over the substrate in the HVPE chamber 204 using HVPE precursor gases GaCl₃ and NH₃ at a temperature of about 550° C. at a chamber pressure of from about 450 Torr. This is followed by growth of a thick u-GaN/n-GaN layer, which in this example is performed using HVPE precursor gases, for example, GaCl₃ and NH₃ at a temperature of about 1050° C. and a chamber pressure of about 450 Torr at block 608.

The GaN film is formed over the substrates by a HVPE process at a temperature between about 700° C. to about 1100° C. by flowing a gallium containing precursor and ammonia. The gallium containing precursor is generated by flowing chlorine gas at a flow rate between about 20 sccm to about 150 sccm over liquid gallium maintained at a temperature between 700° C. to about 950° C. Ammonia is flown to the processing chamber at a flow rate within the range between about 6 SLM to about 20 SLM. The GaN has a growth rate between about 0.3 microns/hour to about 25 microns/hour, with growth rates up to about 100 microns/hour achievable. Flow of the gallium containing precursor is terminated, and flow of the ammonia precursor is continued during cool down of the one or more substrates.

Prior to removal of the one or more substrates from the first deposition chamber, a surface treatment to passivate dangling bonds on the surface of the GaN layer is performed at a temperature of between about 700° C. to about 1000° C. The surface is passivated by flowing precursor gases over the surface of the substrate, such as a magnesium, gallium, indium, or aluminum precursor. A suitable magnesium precursor may be Cp₂Mg. A suitable gallium precursor may be TMG. A suitable indium precursor may be TMI. A suitable aluminum precursor may be TMA. The passivation treatment is performed while flowing a nitrogen containing precursor, such as ammonia.

At block 610, after deposition of the u-GaN and n-GaN layer, the carrier plate 311 is transferred out of either the first MOCVD chamber 202a or the HVPE chamber 204 and into the second MOCVD chamber 202b without breaking vacuum, with the transfer taking place in a high-purity N₂ atmosphere via the transfer chamber 206. After transfer into the second processing chamber, a surface treatment using H₂, NH₃, or a halogen based etching gas (e.g., chlorine based gas, fluorine based gas) is performed at a temperature between about 500° C. and about 1200° C. This treatment removes the passivation layer deposited on the u-GaN/n-GaN layer and/or one or more atomic layers of GaN. The surface treatment is performed by exposing the surface to nitrogen or argon plasma. Regrowth of GaN in the second MOCVD chamber 202b minimizes the dangling bonds or surface reconstruction in the interface resulting in higher luminescence efficiency.

After transfer into the second MOCVD chamber 202b, an additional n-GaN layer is grown at a thickness between about 0.1 μm and about 1 μm on the one or more substrates. In the second MOCVD chamber 202b an InGaN multi-quantum-well (MQW) active layer is grown using MOCVD precursor gases TMG, TMI, and NH₃ in a H₂ carrier gas flow at a temperature of from about 750° C. to about 800° C. and a chamber pressure of from about 100 Torr to about 300 Torr at block 612. The InGaN MQW layer is grown in 10 or more stacked pairs of InGaN and GaN layers bound by GaN barrier layers.

After deposition of the InGaN MQW layer at block 614, one or more treatment processes are performed on the one or more substrates at block 615. The deposition of the InGaN MQW layer is terminated in a nitrogen-rich environment to at least partially passivate the last barrier by preventing dissociation of In in the layer. The flow of ammonia is continued during cool down of the one or more substrates.

In block 615, a surface treatment to passivate dangling bonds on the surface of the InGaN MQW layer is performed at a temperature between about 700° C. to about 1000° C. The surface is passivated by flowing precursor gases over the surface of the substrate, such as a magnesium, gallium, indium, or aluminum precursor. A suitable magnesium precursor may be Cp₂Mg. A suitable gallium precursor may be TMG. A suitable indium precursor may be TMI. A suitable aluminum precursor may be TMA.

In another embodiment of block 615, a surface treatment for the III₂-N layer includes doping the last barrier (i.e., thin GaN layer) of the InGaN MQW layer with a p-type dopant, such as magnesium (Mg), and depositing a p-AlGaN layer thereover. The p-AlGaN layer is grown using MOCVD precursors TMA, TMG, and NH₃ provided in a H₂ carrier gas flow at a temperature of about 1020° C. and a pressure of about 200 Torr. The last barrier of the InGaN MQW layer is doped at 10¹⁸ atoms/cm³, and the p-GaN layer is doped at 10¹⁹ atoms/cm³. This ensures enough holes can be recombined in the InGaN MQW layer, and minimize the non-radiative surface recombination at the interface between the InGaN MQW layer and a p-GaN layer.

After surface treatment of the InGaN MQW layer, at block 615 the carrier plate 311 is transferred out of the second MOCVD chamber 202b and into the third MOCVD chamber 202c without breaking vacuum, with the transfer taking place in a high-purity N₂ atmosphere via the transfer chamber 206. A surface treatment using H₂, NH₃, or a halogen based etching gas (e.g., chlorine based gas, fluorine based gas) is performed at a temperature between about 500° C. and about 1200° C. This treatment partially removes one or more atomic layers of GaN from the surface of the InGaN MQW layer and/or the passivation layer deposited on the InGaN MQW layer in block 615. The surface treatment is performed by exposing the surface to nitrogen or argon plasma. Regrowth of GaN in the third MOCVD chamber 202c minimizes the dangling bonds or surface reconstruction in the interface resulting in higher luminescence efficiency.

In the third MOCVD chamber 202c, additional deposition of the InGaN MQW layer is performed to prevent the growth break from being at the interface between the InGaN MQW layer and a p-AlGaN layer. In the third MOCVD chamber 202c, at block 616, the p-AlGaN layer is grown using MOCVD precursors TMA, TMG, and NH₃ provided in a H₂ carrier gas flow at a temperature of about 1020° C. and a pressure of about 200 Torr. The processes at block 616 may not be required in embodiments in which the p-AlGaN layer is deposited in the second MOCVD chamber 202b. At block 618, the p-GaN layer is grown using flows of TMG, NH₃, Cp₂Mg, and N₂ at a temperature of 1020° C. and a pressure of about 100 Torr. The p-GaN layer is grown in an ammonia free environment using flows of TMG, Cp₂Mg, and N₂ at a temperature of between about 850° C. and about 1050° C. During formation of the p-GaN layer, the one or more substrates are heated at a temperature ramp-up rate between about 5° C./second to about 10° C./second. The NH₃ or N₂ flow is continued during cool down of the one or more substrates.

Optionally, after removal of the carrier plate 311 from each of the HVPE chamber 204, the first MOCVD chamber 202a, the second MOCVD chamber 202b, or the third MOCVD chamber 202c, an in situ chamber clean process may be performed with cleaning gas. The cleaning gas may include any suitable halogen containing gas. Suitable halogen containing gases include fluorine, chlorine, iodine, bromine, and/or other reactive elements. The cleaning gas may be a chlorine containing cleaning gas. Each processing chamber may be cleaned after removal of a carrier plate and prior to insertion of another carrier plate or periodically. The frequency and/or duration of each cleaning may be determined based on the thickness of each layer deposited. For example, a cleaning process performed after deposition of a thin layer would be shorter than a cleaning process performed after deposition of a thicker layer. The first processing chamber may be cleaned after each u-GaN and n-GaN deposition process. The second MOCVD chamber 202b may be cleaned periodically, for example after fifty deposition cycles. The third MOCVD chamber 202c may be cleaned after the removal of each carrier plate 322.

After the p-AlGaN and p-GaN layers are grown, the completed structure is then transferred out of the third MOCVD chamber 202c. The completed structure may either be transferred to the batch loadlock chamber 209 for storage or may exit the processing system 200 via the loadlock chamber 208 and the load station 210.

Multiple carrier plates 311 may be individually transferred into and out of each substrate processing chamber for deposition processes, each carrier plate 311 may then be stored in the batch loadlock chamber 209 and/or the loadlock chamber 208 while either the subsequent processing chamber is being cleaned or the subsequent processing chamber is currently occupied.

While the foregoing is directed to embodiments of the present invention, other and further embodiments of the invention may be devised without departing from the basic scope thereof, and the scope thereof is determined by the claims that follow.

1. A method for fabricating a compound nitride semiconductor structure, comprising:
flowing a first group-III precursor and a first nitrogen containing precursor into a first processing chamber to deposit a first layer over an existing layer disposed on one or more substrates;
transferring the one or more substrates into a second substrate processing chamber without exposing the one or more substrates to atmosphere;
performing a surface treatment on the one or more substrates to remove a portion of the first layer; and
flowing a second group-III precursor and a second nitrogen containing precursor into the second processing chamber to deposit a second layer over the first layer.

2. The method of claim 1, wherein performing a surface treatment comprises flowing an etching gas over the surface of the one or more substrates at an elevated temperature.

3. The method of claim 2, wherein the etching gas is selected from the group consisting of hydrogen gas, ammonia, and a halogen gas.

4. The method of claim 3, wherein the elevated temperature is between about 500° C. and about 1200° C.

5. The method of claim 4, wherein the existing layer comprises a first group-III nitride.

6. The method of claim 5, wherein the first layer comprises a second group-III nitride that is different from the first group-III nitride.

7. The method of claim 6, wherein the second layer comprises a third group-III nitride that is different from the first and second group-III nitrides.

8. The method of claim 4, wherein:
the existing layer comprises GaN;
the first layer comprises InGaN; and
the second layer comprises AlGaN.

9. The method of claim 1, wherein performing a surface treatment comprises introducing a nitrogen or argon plasma over the surface of the one or more substrates.

10. A method for fabricating a compound nitride semiconductor structure, comprising:
flowing a first group-III precursor and a first nitrogen containing precursor into a first processing chamber to deposit a first layer over an existing layer disposed on one or more substrates;
performing a surface treatment on the one or more substrates to at least partially passivate the first layer;
transferring the one or more substrates into a second substrate processing chamber without exposing the one or more substrates to atmosphere; and
flowing a second group-III precursor and a second nitrogen containing precursor into the second processing chamber to deposit a second layer over the first layer.

11. The method of claim 10, wherein performing a surface treatment comprises terminating the flow of the first group-III precursor and the first nitrogen precursor in a nitrogen-rich environment.

12. The method of claim 10, wherein performing a surface treatment comprises forming a passivation layer over the first layer.

13. The method of claim 12, wherein forming the passivation layer comprises flowing a precursor selected from the group consisting of a magnesium precursor, a gallium precursor, and an aluminum precursor over the one or more substrates.

14. The method of claim 13, wherein the surface treatment is performed at a temperature between about 500° C. and about 1200° C.

15. The method of claim 12, further comprising removing the passivation layer after transferring the one or more substrates into the second processing chamber.

16. The method of claim 15, wherein removing the passivation layer comprises flowing an etching gas over the surface of the one or more substrates at an elevated temperature.

17. A method for fabricating a compound nitride semiconductor structure, comprising:
flowing a first group-III precursor and a first nitrogen containing precursor into a first processing chamber to deposit a first layer over an existing layer disposed on one or more substrates;
flowing a p-type dopant over the first layer to lightly dope the surface of the first layer;
transferring the one or more substrates into a second substrate processing chamber without exposing the one or more substrates to atmosphere; and
flowing a second group-III precursor and a second nitrogen containing precursor into the second processing chamber to deposit a second layer over the first layer.

18. The method of claim 17, wherein flowing the second group-III precursor and the second nitrogen containing precursor includes flowing the p-type dopant into the second processing chamber to dope the second layer.

19. The method of claim 18, wherein the second layer is more heavily doped than the first layer.

20. The method of claim 19, wherein the p-type dopant is magnesium.
